(19) United States
(12) Patent Application Publication
(10) Pub. No.: US 2025/0125722 A1
(43) Pub. Date: Apr. 17, 2025

(54) PUMPING CONTROLLER FOR A PLURALITY OF CHARGE PUMP UNITS

(71) Applicant: Silicon Storage Technology, Inc., San Jose, CA (US)

(72) Inventors: Thoan Nguyen, Dong Nai (VN); Nghia Nguyen, Ho Chi Minh (VN); Viet Nguyen, Ho Chi Minh (VN); Son Nguyen, Ho Chi Minh (VN); Hien Lai, Ho Chi Minh (VN); Phuong Nguyen, Ho Chi Minh (VN)

(21) Appl. No.: 18/988,877

(22) Filed: Dec. 19, 2024

Related U.S. Application Data
(63) Continuation-in-part of application No. 18/135,395, filed on Apr. 17, 2023, now Pat. No. 12,206,325.
(60) Provisional application No. 63/442,807, filed on Feb. 2, 2023.

(51) Int. Cl. H02M 3/07; H02M 1/00

(52) U.S. Cl. CPC H02M 3/077; H02M 1/0012

(57) ABSTRACT

In one example, a system comprises a plurality of charge pump units connected in parallel to receive an input voltage and to generate an output voltage greater than the input voltage; and a pumping controller to provide a pumping signal to a first charge pump unit of the plurality of charge pump units and to provide sequentially delayed versions of the pumping signal to the other charge pump units of the plurality of charge pump units, the pumping controller comprising a plurality of circuit blocks, each of the plurality of circuit blocks comprising a delay circuit and a latch.

### PRIORITY CLAIM

This application is a continuation-in-part of U.S. patent application Ser. No. 18/135,395, filed on Apr. 17, 2023, and titled “Pumping Controller for a Plurality of Charge Pump Units,” which claims priority from U.S. Provisional Patent Application No. 63/442,807, filed on Feb. 2, 2023, and titled, “Charge Pump Comprising Latch-Based Self-Oscillating Voltage Regulator,” which are incorporated by reference herein.

### FIELD OF THE INVENTION

Examples of a pumping controller to provide pumping signals to a plurality of charge pump units and associated methods are disclosed.

### BACKGROUND OF THE INVENTION

Charge pumps are commonly used in semiconductor devices to generate voltages greater than the available supply voltage, the available supply voltage commonly denoted as VDD. For example, charge pumps are used in flash memory systems to generate voltages greater than VDD for program, erase, or read operations.

The prior art includes designs with multiple charge pump units operating in parallel. One limitation of these prior art designs is that because each charge pump unit starts its the charge and discharge operation at the same time according to a common pumping signal, resulting in a power surge at the beginning of each charging cycle, which can harm circuits that are sensitive to surges in current or voltage. Another drawback of prior art designs is that if the charge pump reaches a desired voltage level, the charging operation sometimes will continue for a period of time before it is stopped, which results in the output going higher than the desired level.

What is needed is an improved charge pump and pumping controller design.

### SUMMARY OF THE INVENTION

Examples of a pumping controller for a plurality of charge pumps and associated methods are disclosed.

In one example, a system comprises a plurality of charge pump units connected in parallel to receive an input voltage and to generate an output voltage greater than the input voltage; and a pumping controller to provide a pumping signal to a first charge pump unit of the plurality of charge pump units and to provide sequentially delayed versions of the pumping signal to the other charge pump units of the plurality of charge pump units, the pumping controller comprising a plurality of circuit blocks, each of the plurality of circuit blocks comprising a delay circuit and a latch.

In another example, a method comprises comparing a voltage proportional to an output voltage to a reference voltage to generate a comparator output; receiving, by a first NAND gate, the comparator output and a reset-bar signal to generate a latch enable signal; receiving, by a gated D latch the latch enable signal as a latch enable signal for the gated D latch; receiving, by the gated D latch, a data signal on a data port; generating, by the gated D latch, the pumping signal as an output; generating, by respective delay and latch circuits, sequentially delayed versions of the pumping signal; receiving, by a second NAND gate, a first input comprising the delayed version of the pumping signal provided by a last of other pump units in the plurality of pump units and a second input comprising the reset-bar signal and generating an output; and providing, by a delay circuit, a delayed version of the output of the second NAND gate as the data signal to the gated D latch.

In another example, a method comprises comparing a voltage proportional to the output voltage to a reference voltage to generate a comparator output; receiving, by a gated D latch with a reset port, the comparator output as a latch enable signal; receiving, by the gated D latch with a reset port, a data signal on a data port and a reset signal on a reset port; generating, by the gated D latch with a reset port, the pumping signal as an output; generating, by respective delay and latch circuits, the sequentially delayed versions of the pumping signal; receiving, by an inverter, an input comprising the delayed version of the pumping signal provided to a last of other pump units in the plurality of pump units; generating, by the inverter, an output; and providing the output of the inverter as the data signal to the gated D latch with a reset port.

### BRIEF DESCRIPTION OF THE DRAWINGS

FIG. 1 depicts a voltage regulator comprising a pumping controller and a plurality of charge pump units.

FIG. 2 depicts timing diagrams for the voltage regulator of FIG. 1.

FIG. 3 depicts a method of operation of the voltage regulators of FIGS. 1, 5, and 7.

FIG. 4 depicts a method of operation of the voltage regulator of FIG. 1.

FIG. 5 depicts a voltage regulator comprising a pumping controller and a plurality of charge pump units.

FIG. 6 depicts a method of operation of the voltage regulator of FIG. 5.

FIG. 7 depicts a voltage regulator comprising a pumping controller and a plurality of charge pump units.

FIG. 8 depicts a method of operation of the voltage regulator of FIG. 7.

### DETAILED DESCRIPTION OF THE INVENTION

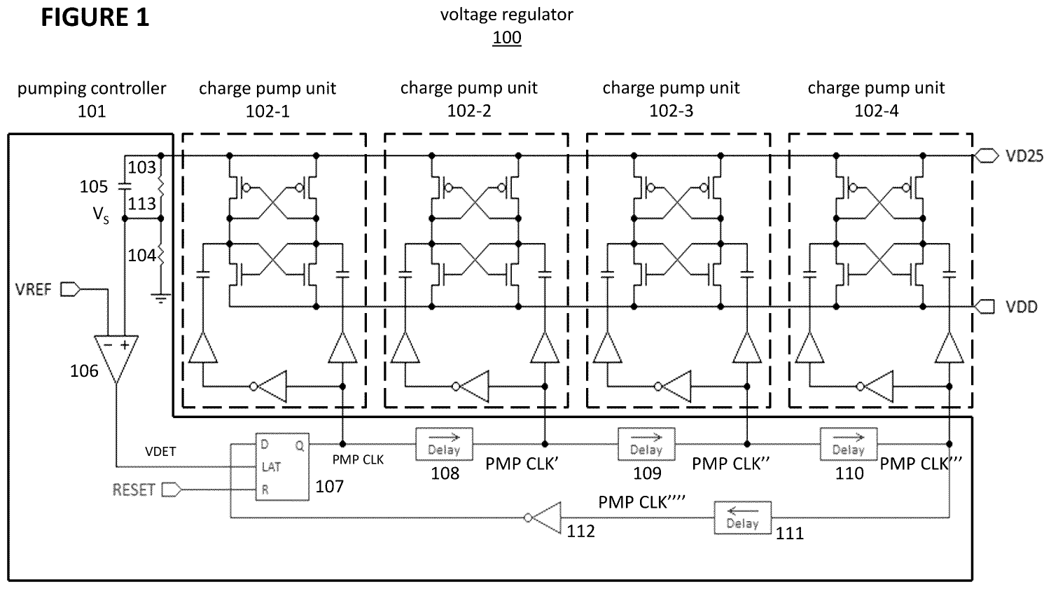

FIG. 1 depicts a system comprising voltage regulator 100. Voltage regulator 100 comprises charge pump units 102-1, 102-2, 102-3, and 102-4. Charge pump units 102-1, 102-2, 102-3, and 102-4 are connected in parallel and each receives an input voltage, VDD, and generates an output voltage, VD25, that is larger than the input voltage. In this example, four charge pump units are connected in parallel to provide output voltage VD25 so as to be able to power an attached load without drooping.

Voltage regulator 100 further comprises pumping controller 101. Pumping controller 101 comprises a voltage divider comprising a first resistor 103 and a second resistor 104, which produces at node 113 a divided voltage, Vs, which is proportional to output voltage VD25. Comparator 106 receives divided voltage Vs on a first, non-inverting input and a reference voltage, VREF, on a second, inverting input and compares them. When V_{S}>VREF, the output, VDET, of comparator 106 is high, and when V_{S}<VREF, the output of comparator 106 is low. Capacitor 105 transfers ripples from VD25 to V_{S} to speed up comparator 106.

Latch 107 is a gated D latch with a reset signal that performs according to the following truth table:

| R | D | LAT | Q |
|---|---|---|---|
| 1 | 0/1 | 0/1 | 0 |
| 0 | 0/1 | 0 | D |
| 0 | 0/1 | 1 | Q |

The signal RESET is provided on the reset port, R, of latch 107, by controller or logic 518. A latch enable port, LAT, of latch 107, receives the signal VDET from comparator 106. A data port, D, of latch 107, receives a signal from inverter 112, described in more detail below. As shown in the above truth table, when the RESET signal on the reset port, R, is asserted, the output, Q, is 0 regardless of the values received by the data port, D, and the latch enable port, LAT. When the RESET signal on the reset port, R, is not asserted and signal received by the latch enable port, LAT, is asserted (which will occur when V_{S}>VREF, signifying that VD25 has reached, or exceeded, the desired voltage), the output, Q, will hold its level regardless of the value received subsequently by the data port, D. When the RESET signal on the R port is not asserted and the signal received by the latch enable port, LAT, is not asserted (which will occur when V_{S}<VREF, signifying that VD25 is less than the desired voltage and additional pumping is desirable), the output, Q, will be whatever is received by the data port, D, at the time.

The output, Q, is the signal PMP CLK, which is provided as a pumping signal to charge pump unit 102-1 and to an input of delay circuit 108. Delay circuit 108 passes through its received signal, PMP CLK, but with an added delay to generate signal PMP CLK′ at the output of delay circuit 108.

PMP CLK′ is provided as a pumping signal to charge pump unit 102-2 and to an input of delay circuit 109. Delay circuit 109 passes through its received signal, PMP CLK′, but with an added delay to generate signal PMP CLK″ at the output of delay circuit 109.

PMP CLK″ is provided as a pumping signal to charge pump unit 102-3 and an input of delay circuit 110. Delay circuit 110 passes through its received signal, PMP CLK″, but with an added delay to generate signal PMP CLK″′ at the output of delay circuit 110.

PMP CLK″′ is provided as a pumping signal to charge pump unit 102-4 and an input of delay circuit 111. Delay circuit 111 passes through its received signal, PMP CLK″′, but with an added delay to generate signal PMP CLK″″ at the output of delay circuit 111. In this example, charge pump unit 102-4 is the last pump unit in the plurality of pump units 102.

Inverter 112 receives signal PMP CLK″″ and generates the inverse of PMP CLK″″, which is then provided as the data signal at the data port, D, of latch 107.

The end result is that pumping controller generates an oscillating signal (PMP CLK) when RESET is low and VDET is low and generates sequentially delayed versions of that oscillating signal (PMP CLK′ PMP CLK″, PMP CLK″40 , and PMP CLK″″). When VDET goes high, PMP CLK remains steady at its existing value and the oscillation of the oscillating signal (PMP CLK), and the sequentially delayed versions of that oscillating signal (PMP CLK′ PMP CLK″, PMP CLK″′, and PMP CLK″″), stops.

Thus, it can be understood that voltage regulator 100 comprises a plurality of charge pump units 102 for receiving an input voltage (VDD) and generating an output voltage (VD25) greater than the input voltage, and a pumping controller 101 for providing a pumping signal (PMP CLK) to a first pump unit of the plurality of pump units (e.g., pump unit 102-1) and providing respective sequentially delayed versions of the pumping signal (PMP CLK′, PMP CLK″, and PMP CLK″′) to the other pump units in the plurality of pump units (e.g., pump units 102-2, 102-3, and 102-4).

Although voltage regulator 100 in this example contains four pump units 102, it is to be understood that voltage regulator 100 alternatively could include fewer than four pump units 102 or more than four pump units 102.

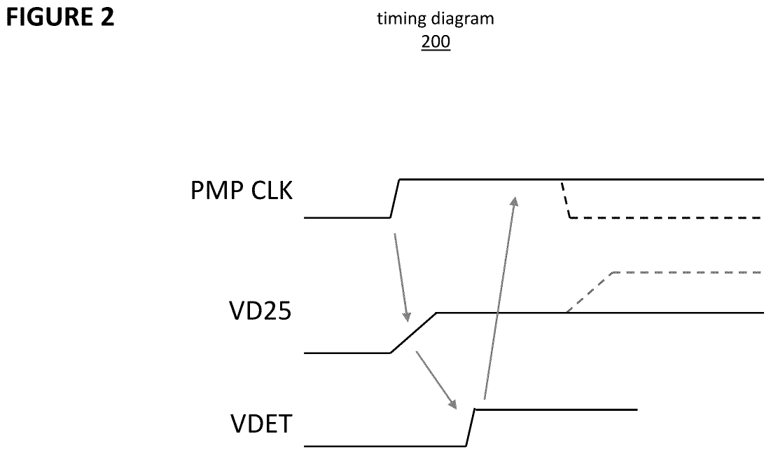

FIG. 2 depicts timing diagram 200 for voltage regulator 100 and shows signals PMP CLK, VD25, and VDET. Unlike in certain prior art systems, the output voltage VD25 does not experience an additional charging cycle that causes the output voltage to go higher than desired (in contrast to the dotted line shown for VD25, which indicates how VD25 might experience an additional voltage boost in certain prior art systems), which is due to VDET being used as the LAT input to latch 107. That is, when VDET goes high, the output of latch 107, PMP CLK, will remain in its present state and will stop oscillating (in contrast to the dotted line shown for PMP CLK, which indicates how PMP CLK might behave in certain prior art systems).

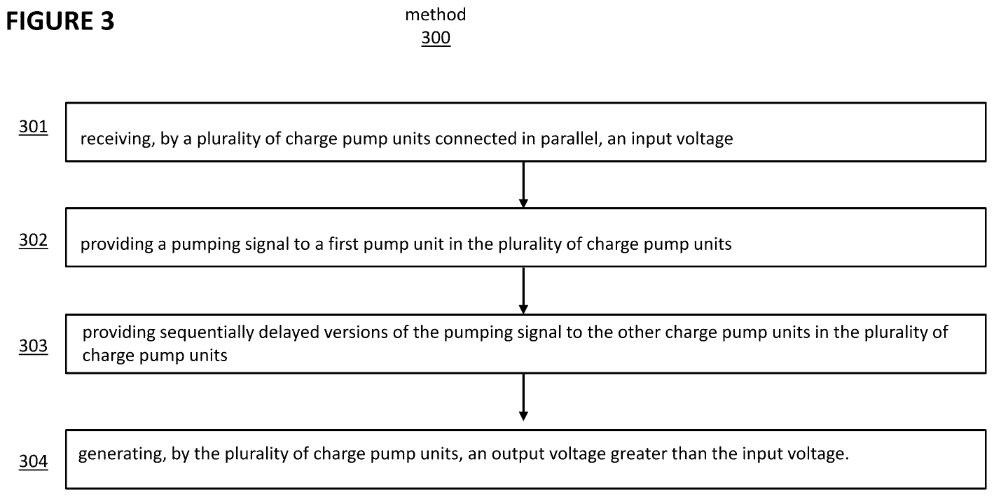

FIG. 3 depicts a method 300 of operation of voltage regulator 100 of FIGS. 1 and 2. Method 300 comprises receiving, by a plurality of charge pump units connected in parallel, an input voltage (301); providing a pumping signal to a first pump unit in the plurality of charge pump units (302); providing sequentially delayed versions of the pumping signal to the other charge pump units in the plurality of charge pump units (303); and (304) generating, by the plurality of charge pump units, an output voltage greater than the input voltage.

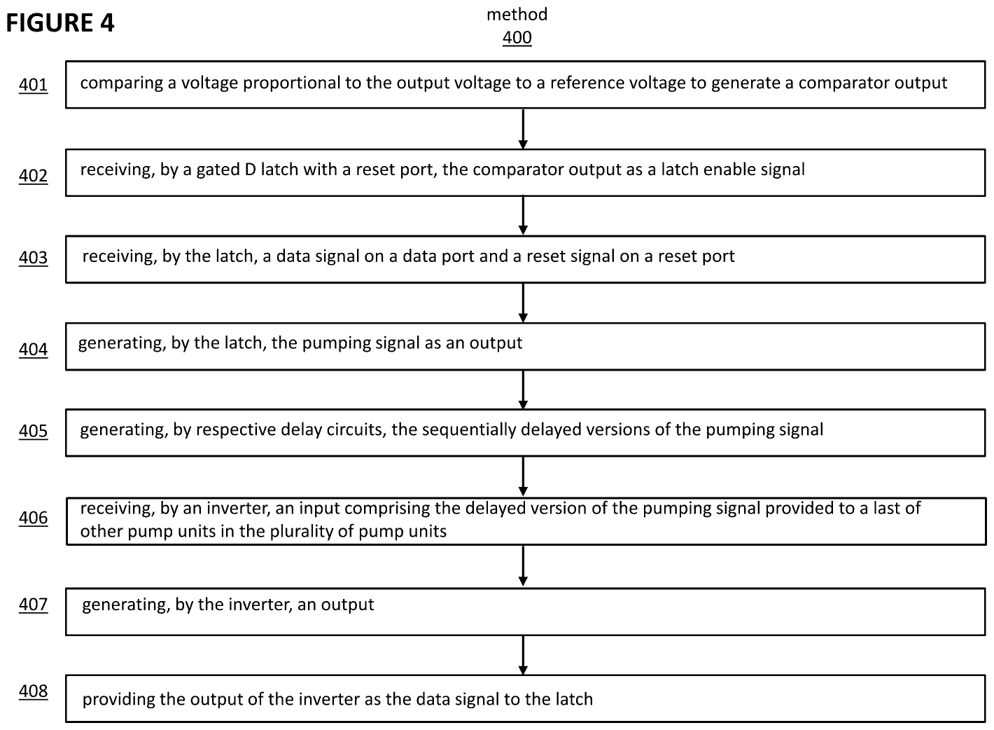

FIG. 4 depicts a method 400. Method 400 is an example of a method to perform providing a pumping signal to a first pump unit in the plurality of charge pump units (302) and providing sequentially delayed versions of the pumping signal to the other charge pump units in the plurality of charge pump units (303) in method 300. Method 400 comprises comparing a voltage proportional to the output voltage to a reference voltage to generate a comparator output (401); receiving, by a gated D latch with a reset port, the comparator output as a latch enable signal (402); receiving, by the gated D latch, a data signal on a data port and a reset signal on a reset port (403); generating, by the gated D latch, the pumping signal as an output (404); generating, by respective delay circuits, the sequentially delayed versions of the pumping signal (405); receiving, by an inverter, an input comprising the delayed version of the pumping signal provided to a last of other pump units in the plurality of pump units (406); generating, by the inverter, an output (407); and providing the output of the inverter as the data signal to the latch (408).

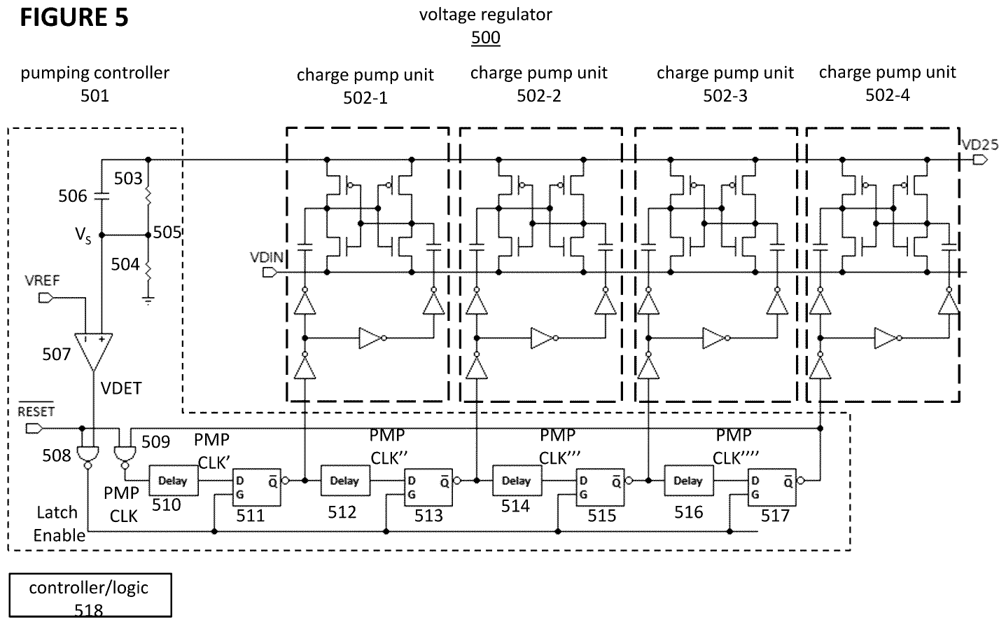

FIG. 5 depicts a system comprising voltage regulator 500. Voltage regulator 500 comprises charge pump units 502-1, 502-2, 502-3, and 502-4. Charge pump units 502-1, 502-2, 502-3, and 502-4 are connected in parallel and each receives an input voltage, VDIN, and generates an output voltage, VD25, that is larger than the input voltage. In this example, four charge pump units are connected in parallel to provide output voltage VD25 so as to be able to power an attached load without drooping.

Voltage regulator 500 further comprises pumping controller 501. Pumping controller 501 comprises a voltage divider comprising a first resistor 503 and a second resistor 504, which produces at node 505 a divided voltage, V_{S}, which is proportional to output voltage VD25. Pumping controller 501 further comprises capacitor 506 and comparator 507. Comparator 507 receives divided voltage V_{S} on a first, non-inverting input and a reference voltage, VREF, on a second, inverting input and compares them. When V_{S}>VREF (signifying that VD25 has reached, or exceeded, the desired voltage), the output, VDET, of comparator 507 is high, and when V_{S}<VREF (signifying that VD25 is less than the desired voltage and additional pumping is desirable), the output of comparator 507 is low. Capacitor 506 transfers ripples from VD25 to V_{S} to speed up comparator 507.

Voltage regulator 500 further comprises NAND gates 508 and 509; latches 511, 513, 515, and 517; and delay circuits 510, 512, 514, and 516.

Delay circuits 510, 512, 514, and 516 each passes through its input as its output but with a delay added. Delay circuit 510 receives PMP CLK and outputs delayed signal PMP CLK′. Delay circuit 512 receives PMP CLK′ from latch 511 and generates delayed signal PMP CLK″. Delay circuit 514 receives PMP CLK″ from latch 513 and generates delayed signal PMP CLK″′. Delay circuit 516 receives PMP CLK″′ from latch 515 and generates delated signal PMP CLK″″.

Latches 511, 513, 515, and 517 each are a gated D latch that performs according to the following truth table:

| G | D | Q | Q̅ |
|---|---|---|---|
| 0 | 0 | Qprev | Q̅prev |
| 0 | 1 | Qprev | Qprev |
| 1 | 0 | 0 | 1 |
| 1 | 1 | 1 | 0 |

The signal RESET-bar is provided as an input to NAND gates 508 and 509. NAND gate 508 also receives VDET from comparator 507, and NAND gate 509 also receives the output Q̅, which is PMP CLK″″, from latch 517. The output of NAND gate 508 is Latch Enable. The output of NAND gate 509 is PMP CLK.

The data port, D, of latch 511, receives PMP CLK′ from delay circuit 510. When Latch Enable is high, PMP CLK′ is propagated to the output of latch 511.

The data port, D, of latch 513, receives PMP CLK″ from delay circuit 512. When Latch Enable is high, PMP CLK″ is propagated to the output of latch 513.

The data port, D, of latch 515, receives PMP CLK″′ from delay circuit 514. When Latch Enable is high, PMP CLK″′ is propagated to the output of latch 515.

The data port, D, of latch 517, receives PMP CLK″″ from delay circuit 516. When Latch Enable is high, PMP CLK″″ is propagated to the output of latch 517.

Delay circuit 510 and latch 511 form a first circuit block, delay circuit 512 and latch 513 form a second circuit block, delay circuit 514 and latch 515 form a third circuit block, and delay circuit 516 and latch 517 form a fourth circuit block.

PMP CLK′ is provided as a pumping signal to charge pump unit 502-1, PMP CLK″ is provided as a pumping signal to charge pump unit 502-2, PMP CLK″′ is provided as a pumping signal to charge pump unit 502-3, and PMP CLK″″ is provided as a pumping signal to charge pump unit 502-4,

Thus, it can be understood that voltage regulator 500 comprises a plurality of charge pump units 502 for receiving an input voltage (VDIN) and generating an output voltage (VD25) greater than the input voltage, and a pumping controller 501 for providing a pumping signal (PMP CLK′) to a first pump unit of the plurality of pump units (e.g., pump unit 502-1) and providing respective sequentially delayed versions of the pumping signal (PMP CLK″, PMP CLK″′, and PMP CLK″″) to the other pump units in the plurality of pump units (e.g., pump units 502-2, 502-3, and 502-4). When V_{S}>VREF (signifying that VD25 has reached, or exceeded, the desired voltage), VDET will go high, and the output of NAND gate will go low, which will cause latches 511, 513, 515, and 517 to hold their respective outputs at the values they held prior to the change in value of VDET, which will cause the pumping action of charge pump units 502-1, 502-2, 502-3, and 502-4 to stop.

Although voltage regulator 500 in this example contains four pump units 502, it is to be understood that voltage regulator 500 alternatively could include fewer than four pump units 502 or more than four pump units 502.

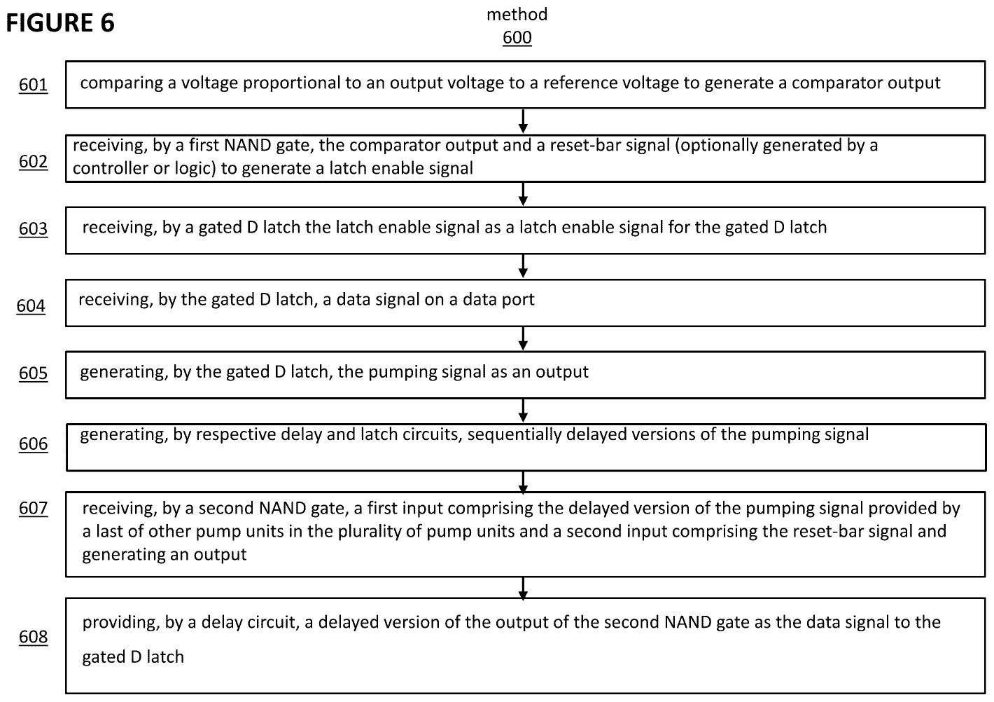

Voltage regulator 500 can perform method 300 shown in FIG. 3 as well as method 600 shown in FIG. 6.

FIG. 6 depicts method 600. Method 600 is an example of a method to perform the actions of providing a pumping signal to a first pump unit in the plurality of charge pump units (302) and providing sequentially delayed versions of the pumping signal to the other charge pump units in the plurality of charge pump units (303) in method 300.

Method 600 comprises comparing a voltage proportional to an output voltage to a reference voltage to generate a comparator output (601); receiving, by a first NAND gate, the comparator output and a reset-bar signal (optionally generated by a controller or logic) to generate a latch enable signal (602); receiving, by a gated D latch the latch enable signal as a latch enable signal for the gated D latch (603); receiving, by the gated D latch, a data signal on a data port (604); generating, by the gated D latch, the pumping signal as an output (605); generating, by respective delay and latch circuits, sequentially delayed versions of the pumping signal (606); receiving, by a second NAND gate, a first input comprising the delayed version of the pumping signal provided by a last of other pump units in the plurality of pump units and a second input comprising the reset-bar signal and generating an output (607); and providing, by a delay circuit, a delayed version of the output of the second NAND gate as the data signal to the gated D latch (608).

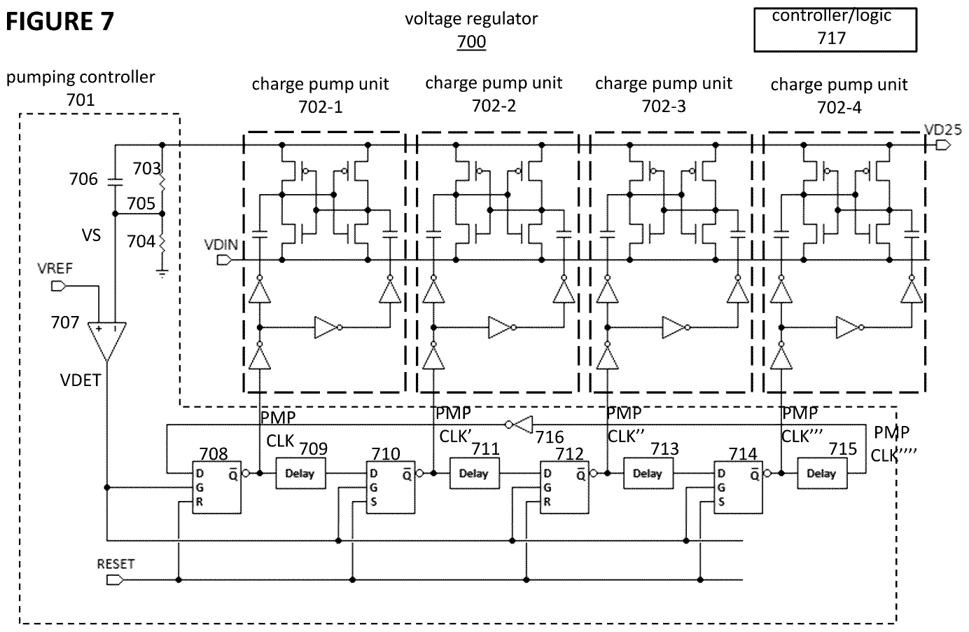

FIG. 7 depicts a system comprising voltage regulator 700. Voltage regulator 700 comprises charge pump units 702-1, 702-2, 702-3, and 702-4. Charge pump units 702-1, 702-2, 702-3, and 702-4 are connected in parallel and each receives an input voltage, VDIN, and generates an output voltage, VD25, that is larger than the input voltage. In this example, four charge pump units are connected in parallel to provide output voltage VD25 so as to be able to power an attached load without drooping.

Voltage regulator 700 further comprises pumping controller 701. Pumping controller 701 comprises a voltage divider comprising a first resistor 703 and a second resistor 704, which produces at node 705 a divided voltage, Vs, which is proportional to output voltage VD25. Pumping controller 701 further comprises capacitor 706 and comparator 707. Comparator 707 receives divided voltage V_{S} on a first, inverting input and a reference voltage, VREF, on a second, non-inverting input and compares them. When V_{S}>VREF (signifying that VD25 has reached, or exceeded, the desired voltage), the output, VDET, of comparator 707 is low, and when V_{S}<VREF (signifying that VD25 is less than the desired voltage and additional pumping is desirable), the output of comparator 707 is high. Capacitor 706 transfers ripples from VD25 to V_{S} to speed up comparator 707.

Voltage regulator 700 further comprises latches 708, 710, 712, and 714; delay circuits 709, 711, 713, and 715; and inverter 716.

Delay circuits 709, 711, 713, and 715 each passes through its input as its output but with a delay added. Delay circuit 709 receives PMP CLK from latch 708 and outputs delayed signal PMP CLK′. Delay circuit 711 receives PMP CLK′ from latch 710 and generates delayed signal PMP CLK″. Delay circuit 713 receives PMP CLK″ from latch 712 and generates delayed signal PMP CLK″′. Delay circuit 715 receives PMP CLK″′ from latch 714 and generates delated signal PMP CLK″″.

Latches 708 and 712 each is a gated D latch with a reset signal that performs according to the following truth table:

| R | G | D | Q | Q̅ |
|---|---|---|---|---|
| 1 | 1 | 0 | 0 | 1 |
| 1 | 1 | 1 | 0 | 1 |
| 1 | 0 | 0 | 0 | 1 |
| 1 | 0 | 1 | 0 | 1 |
| 0 | 1 | 0 | 0 | 1 |
| 0 | 1 | 1 | 1 | 0 |
| 0 | 0 | 0 | Q_{PREV} | Q̅_{PREV} |
| 0 | 0 | 1 | Q_{PREV} | Q̅_{PREV} |

The signal RESET is provided on the reset port, R, of latches 708 and 712, by other controller or logic 717. A latch enable port, G, of latches 708 and 712 receives the signal VDET from comparator 707.

As shown in the above truth table, when the RESET signal on the reset port, R, is asserted (R=1), the output, Q, of each latch 708 and 712 is 0 and Q̅ is 1 regardless of the values received by the respective data port, D, and the latch enable port, G.

When the RESET signal on the reset port, R, is not asserted (R=0) and the signal received by the latch enable port, G, is not asserted (G=0) (which will occur when V_{S}>VREF, signifying that VD25 has reached, or exceeded, the desired voltage), the output, Q, and Q̅ will hold their respective levels regardless of the value received subsequently by the data port, D.

When the RESET signal on the R port is not asserted (R=0) and the signal received by the latch enable port, G, is asserted (G=1) (which will occur when V_{S}<VREF, signifying that VD25 is less than the desired voltage and additional pumping is desirable), the output, Q, will be whatever is received by the data port, D, at the time, and Q̅ will be the complement of that value.

Latches 710 and 714 each is a gated D latch with a set signal that performs according to the following truth table:

| S | G | D | Q | Q̅ |
|---|---|---|---|---|
| 1 | 1 | 0 | 1 | 0 |
| 1 | 1 | 1 | 1 | 0 |
| 1 | 0 | 0 | 1 | 0 |
| 1 | 0 | 1 | 1 | 0 |
| 0 | 1 | 0 | 0 | 1 |
| 0 | 1 | 1 | 1 | 0 |
| 0 | 0 | 0 | Q_{PREV} | Q̅_{PREV} |
| 0 | 0 | 1 | Q_{PREV} | Q̅_{PREV} |

The signal RESET is provided on the set port, S, of latches 710 and 714, by other controller or logic 717. A latch enable port, G, of latches 710 and 714 receives the signal VDET from comparator 707.

As shown in the above truth table, when the RESET signal on the set port, S, is asserted (S=1), the output, Q, of each latch 710 and 714 is 1 and Q̅ is 0 regardless of the values received by the respective data port, D, and the latch enable port, G.

When the RESET signal on the set port, S, is not asserted (S=0) and the signal received by the latch enable port, G, is not asserted (G=0) (which will occur when V_{S}>VREF, signifying that VD25 has reached, or exceeded, the desired voltage), the output, Q, and Q̅ will hold their respective levels regardless of the value received subsequently by the data port, D.

When the RESET signal on the S port is not asserted (S=0) and the signal received by the latch enable port, G, is asserted (G=1) (which will occur when V_{S}<VREF, signifying that VD25 is less than the desired voltage and additional pumping is desirable), the output, Q, will be whatever is received by the data port, D, at the time, and Q̅ will be the complement of that value.

The data port, D, of latch 708, receives the inverse of PMP CLK″″ which is also PMP CLK. When VDET is high (and RESET is low), PMP CLK is propagated to the output of latch 708.

The data port, D, of latch 710, receives PMP CLK′ from delay circuit 709. When VDET is high (and RESET is low), PMP CLK′ is propagated to the output of latch 710.

The data port, D, of latch 712, receives PMP CLK″ from delay circuit 711. When VDET is high (and RESET is low), PMP CLK″ is propagated to the output of latch 712.

The data port, D, of latch 714, receives PMP CLK″′ from delay circuit 709. When VDET is high (and RESET is low), PMP CLK″′ is propagated to the output of latch 714.

Latch 708 and delay circuit 709 form a first circuit block, latch 710 and delay circuit 711 form a second circuit block, latch 712 and delay circuit 713 form a third circuit block, and latch 714 and delay circuit 715 form a fourth circuit block.

PMP CLK is provided as a pumping signal to charge pump unit 702-1, PMP CLK′ is provided as a pumping signal to charge pump unit 702-2, PMP CLK″ is provided as a pumping signal to charge pump unit 702-3, and PMP CLK″′ is provided as a pumping signal to charge pump unit 702-4,

Thus, it can be understood that voltage regulator 700 comprises a plurality of charge pump units 702 for receiving an input voltage (VDIN) and generating an output voltage (VD25) greater than the input voltage, and a pumping controller 701 for providing a pumping signal (PMP CLK) to a first pump unit of the plurality of pump units (e.g., pump unit 702-1) and providing respective sequentially delayed versions of the pumping signal (PMP CLK′, PMP CLK″, and PMP CLK″′) to the other pump units in the plurality of pump units (e.g., pump units 702-2, 702-3, and 702-4).

When V_{S}>VREF (signifying that VD25 has reached, or exceeded, the desired voltage), VDET will go high and latches 511, 513, 515, and 517 will hold their respective outputs at the values they held prior to the change in value of VDET, which will cause the pumping action of charge pump units 702-1, 702-2, 702-3, and 702-4 to stop.

Although voltage regulator 700 in this example contains four pump units 702, it is to be understood that voltage regulator 700 alternatively could include fewer than four pump units 702 or more than four pump units 702.

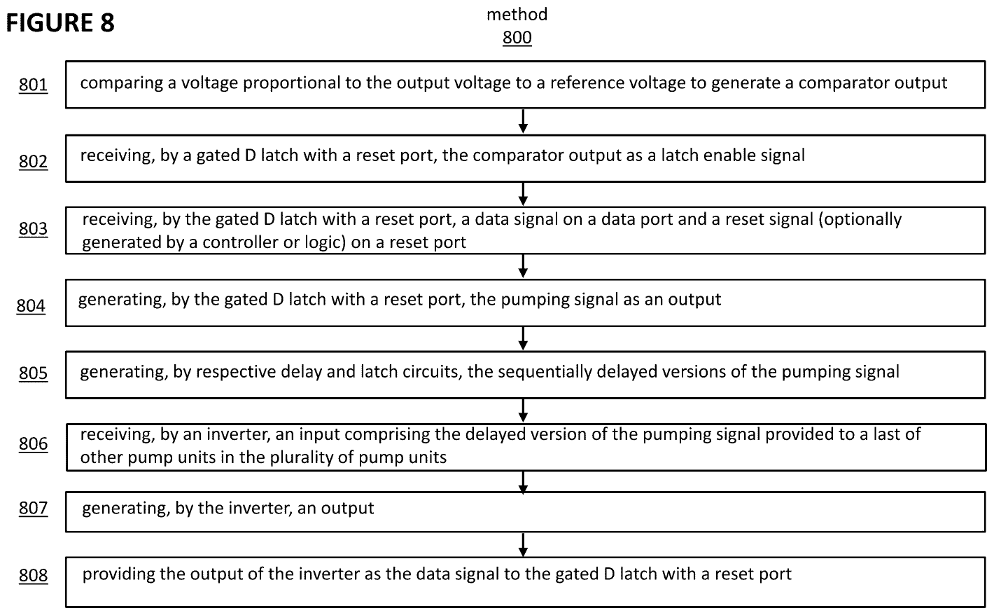

Voltage regulator 700 can perform method 300 shown in FIG. 3 as well as method 800 shown in FIG. 8.

FIG. 8 depicts a method 800. Method 800 is an example of a method to perform the steps of providing a pumping signal to a first pump unit in the plurality of charge pump units (302) and providing sequentially delayed versions of the pumping signal to the other charge pump units in the plurality of charge pump units (303) in method 300.

Method 800 comprises comparing a voltage proportional to the output voltage to a reference voltage to generate a comparator output (801); receiving, by a gated D latch with a reset port, the comparator output as a latch enable signal (802); receiving, by the gated D latch with a reset port, a data signal on a data port and a reset signal (optionally generated by a controller or logic) on a reset port (803); generating, by the gated D latch with a reset port, the pumping signal as an output (804); generating, by respective delay and latch circuits, the sequentially delayed versions of the pumping signal (805); receiving, by an inverter, an input comprising the delayed version of the pumping signal provided to a last of other pump units in the plurality of pump units (806); generating, by the inverter, an output (807); and providing the output of the inverter as the data signal to the gated D latch with a reset port (808).

It should be noted that, as used herein, the terms “over” and “on” both inclusively include “directly on” (no intermediate materials, elements or space disposed therebetween) and “indirectly on” (intermediate materials, elements or space disposed therebetween. For example, forming an element “over a substrate” can include forming the element directly on the substrate with no intermediate materials/elements therebetween, as well as forming the element indirectly on the substrate with one or more intermediate materials/elements there between.

It should be noted that, in methods 400 and 800, the gated D latch with a reset port can be interchanged with a gated D latch with a set port.

It should be noted that, in method 600, the NAND gates can be interchanged with various combinations of NOR, AND, and OR gates.

What is claimed is:

1. A system comprising:
a plurality of charge pump units connected in parallel to receive an input voltage and to generate an output voltage greater than the input voltage; and
a pumping controller to provide a pumping signal to a first charge pump unit of the plurality of charge pump units and to provide sequentially delayed versions of the pumping signal to the other charge pump units of the plurality of charge pump units, the pumping controller comprising a plurality of circuit blocks, each of the plurality of circuit blocks comprising a delay circuit and a latch.

2. The system of claim 1, wherein each delay circuit in each of the plurality of circuit blocks receives an input and provides a delayed version of the input as an output.

3. The system of claim 1, wherein the pumping controller comprises:
a voltage divider to receive the output voltage and generate a lower voltage at a node, the voltage divider comprising a first resistor coupled to a second resistor at the node, wherein the first resistor receives the output voltage; and
a capacitor coupled between the output voltage and the node.

4. The system of claim 3, wherein the pumping controller comprises:
a comparator comprising a first input coupled to the node, a second input coupled to a reference voltage, and an output.

5. The system of claim 1, wherein in each of the plurality of circuit blocks, an output of the delay circuit is provided as a data input to the latch.

6. The system of claim 1, wherein in each of the plurality of circuit blocks, an output of the latch is provided as an input to the delay circuit.

7. The system of claim 1, wherein each latch in each of the plurality of circuit blocks generates a latch output in response to a data signal received on a data port and a gate signal received on a gate port.

8. The system of claim 1, wherein each latch in each of the plurality of circuit blocks generates a latch output in response to an enable signal received on a latch enable port, a data signal received on a data port, and a reset signal received on one of a reset port and a set port.

9. The system of claim 8, wherein the reset signal is provided by a controller.

10. The system of claim 8, wherein the reset signal is provided by logic.

11. The system of claim 8, comprising an inverter to receive as an input the delayed version of the pumping signal provided to a last pump unit of the other pump units of the plurality of pump units and to generate an output.

12. The system of claim 11, wherein the output of the inverter is the data signal provided to the data port of the circuit block that provides the pumping signal to the first charge pump unit.

13. The system of claim 8, wherein the pumping controller comprises:
a voltage divider to receive the output voltage and generate a lower voltage at a node, the voltage divider comprising a first resistor coupled to a second resistor at the node, wherein the first resistor receives the output voltage; and
a capacitor coupled between the output voltage and the node.

14. The system of claim 13, wherein the pumping controller comprises:
a comparator comprising a first input coupled to the node, a second input coupled to a reference voltage, and an output.

15. The system of claim 14, wherein the enable signal is the output of the comparator.

16. A method comprising:
comparing a voltage proportional to an output voltage to a reference voltage to generate a comparator output;
receiving, by a first NAND gate, the comparator output and a reset-bar signal to generate a latch enable signal;
receiving, by a gated D latch the latch enable signal as a latch enable signal for the gated D latch;
receiving, by the gated D latch, a data signal on a data port;
generating, by the gated D latch, the pumping signal as an output;
generating, by respective delay and latch circuits, sequentially delayed versions of the pumping signal;
receiving, by a second NAND gate, a first input comprising the delayed version of the pumping signal provided by a last of other pump units in the plurality of pump units and a second input comprising the reset-bar signal and generating an output; and
providing, by a delay circuit, a delayed version of the output of the second NAND gate as the data signal to the gated D latch.

17. The method of claim 16, comprising:
generating the reset-bar signal by a controller.

18. The method of claim 16, comprising:
generating the reset-bar signal by logic.

19. A method comprising:
comparing a voltage proportional to the output voltage to a reference voltage to generate a comparator output;
receiving, by a gated D latch with a reset port, the comparator output as a latch enable signal;
receiving, by the gated D latch with a reset port, a data signal on a data port and a reset signal on a reset port;
generating, by the gated D latch with a reset port, the pumping signal as an output;
generating, by respective delay and latch circuits, the sequentially delayed versions of the pumping signal;
receiving, by an inverter, an input comprising the delayed version of the pumping signal provided to a last of other pump units in the plurality of pump units;
generating, by the inverter, an output; and
providing the output of the inverter as the data signal to the gated D latch with a reset port.

20. The method of claim 19, comprising:
generating the reset signal by a controller.

21. The method of claim 19, comprising:
generating the reset-bar signal by logic.
